(19) United States
(12) Patent Application Publication
(10) Pub. No.: US 2018/0340252 A1
(43) Pub. Date: Nov. 29, 2018

(54) SYSTEM AND METHOD FOR REDUCING ATTRACTIVE FORCES BETWEEN A DEPOSITION MASK AND SUBSTRATE AND A DEPOSITION SYSTEM AND METHOD UTILIZING THE SAME

(71) Applicant: eMagin Corporation, Hopewell Junction, NY (US)

(72) Inventors: Fridrich VAZAN, Pittsford, NY (US); Evan P. DONOGHUE, Hopewell Junction, NY (US); Kerry TICE, Hopewell Junction, NY (US); Ilyas I. KHAYRULLIN, Hopewell Junction, NY (US); Tariq ALI, Hopewell Junction, NY (US); Qi WANG, Hopewell Junction, NY (US); Amalkumar P. GHOSH, Hopewell Junction, NY (US)

(21) Appl. No.: 15/988,621

(22) Filed: May 24, 2018

Related U.S. Application Data
(60) Provisional application No. 62/510,580, filed on May 24, 2017.

(51) Int. Cl. C23C 14/04; C23C 14/50

(52) U.S. Cl. CPC C23C 14/042; C23C 14/50

(57) ABSTRACT

A system and method for reducing attractive forces between a deposition mask and a substrate is provided that enables high-resolution direct deposition of a patterned layer of material on a substrate using electrostatic chucks for holding the substrate and the shadow mask. A charge-dissipating shadow mask is utilized that comprises a thin conductive layer on the surface of the membrane of the shadow mask. The conductive layer helps to dissipate the charge that accumulates on the membrane of the shadow mask, thereby reducing the attractive forces between the substrate and the shadow mask. As a result, the shadow mask and substrate can be placed in closer proximity to each other than would be possible without the charge-dissipating shadow mask, thereby reducing feathering effects and enabling higher resolution direct deposition.

### STATEMENT OF RELATED CASES

This application claims priority to U.S. Provisional Application Ser. No. 62/510,580, filed May 24, 2017, whose entire disclosure is incorporated herein by reference. Further, U.S. patent application Ser. No. 15/597,635 filed on May 17, 2017, U.S. patent application Ser. No. 15/602,939 filed on May 23, 2017, U.S. patent application Ser. No. 15/968,443 filed on May 1, 2018, U.S. Provisional Application 62/340,793 filed on May 24, 2016, PCT Application No. PCT/US17/33161 filed on May 17, 2017, and PCT Application No. PCT/US17/34203 filed on May 24, 2017 are incorporated herein by reference in their entirety for their disclosure of high-precision shadow-mask-deposition systems and methods thereof.

### FIELD OF THE INVENTION

The present invention relates to thin-film deposition in general, and, more particularly, shadow mask deposition systems.

### BACKGROUND OF THE INVENTION

Shadow-mask-based deposition is a process by which a layer of material is deposited onto the surface of a substrate such that the desired pattern of the layer is defined during the deposition process itself. This is deposition technique is sometimes referred to as “direct patterning.”

In a typical shadow mask deposition process, the desired material is vaporized at a source that is located at a distance from the substrate, with a shadow mask positioned between them. As the vaporized atoms of the material travel toward the substrate, they pass through a set of through-holes in the shadow mask, which is positioned in contact with or just in front of the substrate surface. The through-holes (i.e., apertures) are arranged in the desired pattern for the material on the substrate. As a result, the shadow mask blocks passage of all vaporized atoms except those that pass through the through-holes, which deposit on the substrate surface in the desired pattern. Shadow-mask-based deposition is analogous to silk-screening techniques used to form patterns (e.g., uniform numbers, etc.) on articles of clothing or stenciling used to develop artwork.

Shadow-mask-based deposition has been used for many years in the integrated-circuit (IC) industry to deposit patterns of material on substrates, due, in part, to the fact that it avoids the need for patterning a material layer after it has been deposited. As a result, its use eliminates the need to expose the deposited material to harsh chemicals (e.g., acid-based etchants, caustic photolithography development chemicals, etc.) to pattern it. In addition, shadow-mask-based deposition requires less handling and processing of the substrate, thereby reducing the risk of substrate breakage and increasing fabrication yield. Furthermore, many materials, such as organic materials, cannot be subjected to photolithographic chemicals without damaging them, which makes depositing such materials by shadow mask a necessity.

Unfortunately, the feature resolution that can be obtained by conventional shadow-mask deposition is diminished due to the fact that the deposited material tends to spread laterally after passing through the shadow mask—referred to as “feathering.” Feathering increases with the magnitude of the separation between the substrate and the shadow mask. As a result, this separation is typically kept as small as possible without compromising the integrity of the chucks that hold the substrate and shadow mask.

Shadow-mask-based deposition has been used for fabricating high brightness organic light-emitting diode (OLED) microdisplays. One method of fabricating an OLED microdisplay is to use a shadow mask comprised of a silicon wafer with a thin membrane (hereinafter “membrane”) comprised of one or several materials (such as silicon nitride, silicon dioxide, aluminum oxide, etc.) which has been patterned and etched to create a very rigid and flat, high resolution shadow mask. This is necessary in situations where the critical pixel dimension is below that which can be patterned using conventional fine metal masks (<20 micron).

The membrane shadow mask and active matrix CMOS silicon substrate must each be held individually and then aligned relative to each other using a high precision alignment system. Due to the small pixel dimensions, the mask and substrate must be in very close proximity (from 0-10 microns) to prevent the evaporated organic material from spreading out onto adjacent pixels via feathering. This close proximity prevents the use of most wafer chucks or clamping mechanisms that use a mechanical force applied to the front of the wafer.

One possible method of holding both the shadow mask and the substrate is an electrostatic chuck, which applies a large voltage through a dielectric across the back of a wafer. By using a standard circular electrostatic chuck to hold the substrate wafer and an annular electrostatic chuck to hold the shadow mask (the annular shape being required to allow the evaporated organics to pass through the shadow mask and be deposited on the substrate), both mask and substrate can be held in close proximity with nothing between them to limit the spacing between them from approaching zero microns or full contact.

During operation, image charges from the electrostatic clamping force may form on the surface of both shadow mask and substrate, particularly when large voltages are applied. In conventional use with only a single electrostatic chuck this is not problematic, but as the shadow mask and substrate are moved into extremely close proximity, these charges may attract and result in the shadow mask and substrate sticking together, particularly as each is very flat and rigid.

Depending on the strength of the attractive force between the shadow mask and substrate, this may pose a number of problems. In mild cases, alignment of the substrate and shadow mask may be impeded by the attractive force between the two objects. In more severe cases, the shadow mask and substrate may stick together and become nearly impossible to separate. Both situations are problematic and can lead to significant damage and loss of both materials and time.

In practice, therefore, critical features formed by prior-art shadow-mask-based deposition techniques are typically separated by relatively large areas of open space to accommodate feathering, which limits the device density that can be obtained. For example, each pixel of an active-matrix organic light-emitting-diode (AMOLED) display normally includes several regions of organic light-emitting material, each of which emits a different color of light. Due to feathering issues, prior-art AMOLED displays have typically been restricted to approximately 600 pixels-per-inch (ppi) or less, which is insufficient for many applications, such as near-to-eye augmented reality and virtual-reality applications. In addition, the need for large gaps within and between the pixels gives rise to a reduced pixel fill factor, which reduces display brightness. As a result, the current density through the organic layers must be increased to provide the desired brightness, which can negatively impact display lifetime.

Thus, there is a need for processes and systems that will enable high-resolution direct deposition using shadow-masks.

### SUMMARY OF THE INVENTION

An object of the invention is to solve at least the above problems and/or disadvantages and to provide at least the advantages described hereinafter.

The present invention enables high-resolution direct deposition of a patterned layer of material on a substrate using electrostatic chucks for holding the substrate and the shadow mask. The present invention utilizes a charge-dissipating shadow mask that comprises a thin conductive layer on the surface of the membrane of the shadow mask. The conductive layer helps to dissipate the charge that accumulates on the membrane of the shadow mask, thereby reducing the attractive forces between the substrate and the shadow mask. As a result, the shadow mask and substrate can be placed in closer proximity to each other than would be possible without the charge-dissipating shadow mask, thereby reducing feathering effects and enabling higher resolution direct deposition.

An embodiment of the invention is a charge-dissipating shadow mask, comprising: a membrane layer having a first region that comprises an aperture pattern comprising at least one aperture; and a conductive layer disposed on the membrane layer.

Another embodiment of the invention is a system for depositing a pattern of material on a substrate, comprising: a first electrostatic chuck for holding the substrate via an electrostatic force; a charge dissipating shadow mask, wherein the charge dissipating shadow mask comprises: a membrane layer having a first region that comprises an aperture pattern comprising at least one aperture, and a conductive layer disposed on the membrane layer; a second electrostatic chuck for holding the charge dissipating shadow mask via an electrostatic force; and an alignment system for controlling the relative position of the first chuck and the second chuck to align the shadow mask and the substrate.

Another embodiment of the invention is a method of forming a shadow mask, comprising: providing a substrate; forming a membrane layer on the substrate; forming an aperture pattern in a first region of the membrane layer, wherein the aperture pattern comprises at least one aperture that extends completely through the membrane layer; forming a conductive layer on the membrane layer; and forming a cavity in the substrate, wherein the formation of the cavity releases the first region of the membrane layer to define a membrane.

### BRIEF DESCRIPTION OF THE DRAWINGS

The invention will be described in detail with reference to the following drawings in which like reference numerals refer to like elements wherein:

FIG. 1 is a schematic drawing of a high-resolution, direct-patterning deposition system, in accordance with an illustrative embodiment of the present invention;

FIG. 2A is a schematic drawing of a cross-sectional view of a charge-dissipating shadow mask, in accordance with a first illustrative embodiment of the present invention;

FIG. 2B is a schematic drawing of a cross-sectional view of a charge-dissipating shadow mask, in accordance with a second illustrative embodiment of the present invention;

FIG. 2C is a schematic drawing of a cross-sectional view of a charge-dissipating shadow mask, in accordance with a third illustrative embodiment of the present invention;

FIG. 3A is a schematic drawing of a cross-sectional view of a substrate chuck, in accordance with an illustrative embodiment of the present invention;

FIG. 3B is a schematic drawing of a cross-sectional view of a substrate chuck while holding a substrate, in accordance with an illustrative embodiment of the present invention;

FIGS. 4A-B are schematic drawings of top and cross-section views, respectively, of a mask chuck, in accordance with an illustrative embodiment of the present invention;

FIG. 5 is a cross-sectional view of charge-dissipating shadow mask mounted in mask chuck, in accordance with an illustrative embodiment of the present invention;

FIG. 6 is a schematic drawing of a cross-sectional view of a substrate and charge-dissipating shadow mask in alignment for deposition of material, in accordance with an illustrative embodiment of the present invention;

FIG. 7A is a schematic drawing of a cross-sectional view of a portion of a mask chuck, in accordance with another illustrative embodiment of the present invention;

FIG. 7B is a schematic drawing of a cross-sectional view of a portion of a mask chuck, in accordance with another illustrative embodiment of the present invention;

FIGS. 8A-B are schematic drawings of top and cross-section views, respectively, of a mask chuck in accordance with another illustrative embodiment of the present invention;

FIG. 9 is a flowchart of methods of an operation for forming a patterned layer of material on a substrate, in accordance with an illustrative embodiment of the present invention;

FIG. 10 depicts operations of a method for forming a charge-dissipating shadow mask, in accordance with an illustrative embodiment of the present invention;

FIG. 11A depicts a schematic drawing of a cross-sectional view of nascent a charge-dissipating shadow mask after the formation of a membrane layer and a mask layer;

FIG. 11B depicts a schematic drawing of a cross-sectional view of nascent charge-dissipating shadow mask after the definition of apertures and a mask;

FIG. 11D depicts a schematic drawing of a cross-sectional view of nascent charge-dissipating shadow mask after the formation of a cavity, for the charge-dissipating shadow mask embodiment in which the conductive layer does not contact the substrate;

FIG. 11E depicts a schematic drawing of a cross-sectional view of nascent charge-dissipating shadow mask after the formation of a cavity, for the charge-dissipating shadow mask embodiment in which the conductive layer contacts the substrate;

FIG. 11F depicts a schematic drawing of a cross-sectional view of nascent charge-dissipating shadow mask after the deposition of a conductive layer on the membrane layer;

FIG. 11G depicts a schematic drawing of a cross-sectional view of nascent charge-dissipating shadow mask after the formation of a cavity, for the charge-dissipating shadow mask embodiment in which the conductive layer contacts the substrate; and

FIG. 11H depicts a schematic drawing of a cross-sectional view of nascent charge-dissipating shadow mask after the formation of a cavity, for the charge-dissipating shadow mask embodiment in which the conductive layer extends down a side of the membrane layer and the substrate.

### DETAILED DESCRIPTION OF PREFERRED EMBODIMENTS

In the following detailed description of various embodiments of the system and method of the present invention, numerous specific details are set forth in order to provide a thorough understanding of various aspects of one or more embodiments. However, the one or more embodiments may be practiced without some or all of these specific details. In other instances, well-known methods, procedures, and/or components have not been described in detail so as not to unnecessarily obscure aspects of embodiments.

While preferred embodiments are disclosed, still other embodiments of the system and method of the present invention will become apparent to those skilled in the art from the following detailed description, which shows and describes illustrative embodiments. As will be realized, the following disclosure is capable of modifications in various obvious aspects, all without departing from the spirit and scope of the present invention. Also, the reference or non-reference to a particular embodiment of the invention shall not be interpreted to limit the scope of the present invention.

One aspect of the present invention is the use of a charge-dissipating shadow mask that comprises a thin conductive layer on the surface of the membrane of the shadow mask. The conductive layer helps to dissipate the charge that accumulates on the membrane of the shadow mask. The conductive layer can be positioned solely on top of the membrane of the shadow mask or it may contact the silicon wafer of the shadow mask through the membrane or it may be grounded. The conductive layer can fully cover or only partially cover the surface of the shadow mask.

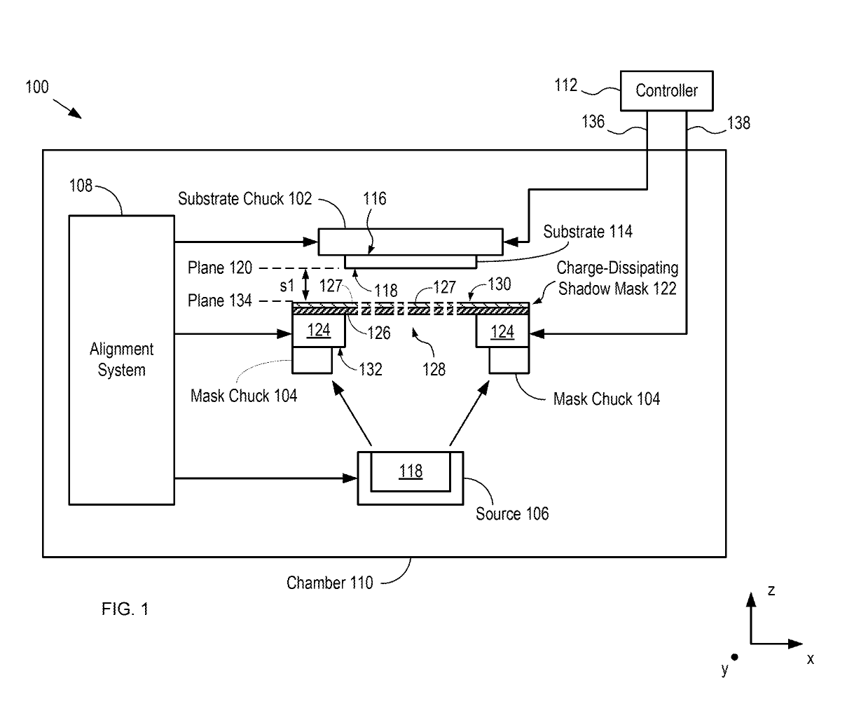

FIG. 1 is a schematic drawing of a high-resolution, direct-patterning deposition system that incorporates a charge-dissipating shadow mask 122, in accordance with an illustrative embodiment of the present invention. The system 100 includes substrate chuck 102, a mask chuck 104, source 106, alignment system 108, vacuum chamber 110, and controller 112. The system 100 is operative for evaporating a desired pattern of material onto a substrate surface without the need for subsequent subtractive patterning operations, such as photolithography and etching.

System 100 is described herein with respect to the deposition of a pattern of light-emitting organic material on a glass substrate as part of the fabrication of an AMOLED display. However, it will be clear to one skilled in the art, after reading this Specification, that the present invention can be directed toward the formation of directly patterned layers of virtually any thin- and thick-film material (organic or inorganic) on any of a wide range of substrates, such as semiconductor substrates (e.g., silicon, silicon carbide, germanium, etc.), ceramic substrates, metal substrates, plastic substrates, and the like.

Further, although the illustrative embodiment is a thermal evaporation system, one skilled in the art will recognize, after reading this Specification, that the present invention can be directed toward virtually any material-deposition process, such as e-beam evaporation, sputtering, and the like. Still further, although the depicted example is a deposition system suitable for use in single-substrate planar processing, the present invention is also suitable for use in other fabrication approaches, such as cluster-tool processing, track processing, roll-to-roll processing, reel-to-reel processing, etc. As a result, the present invention is suitable for use in myriad applications including, without limitation, packaging applications, integrated-circuit fabrication, MEMS fabrication, nanotechnology device fabrication, ball-grid array (BGA) fabrication, and the like.

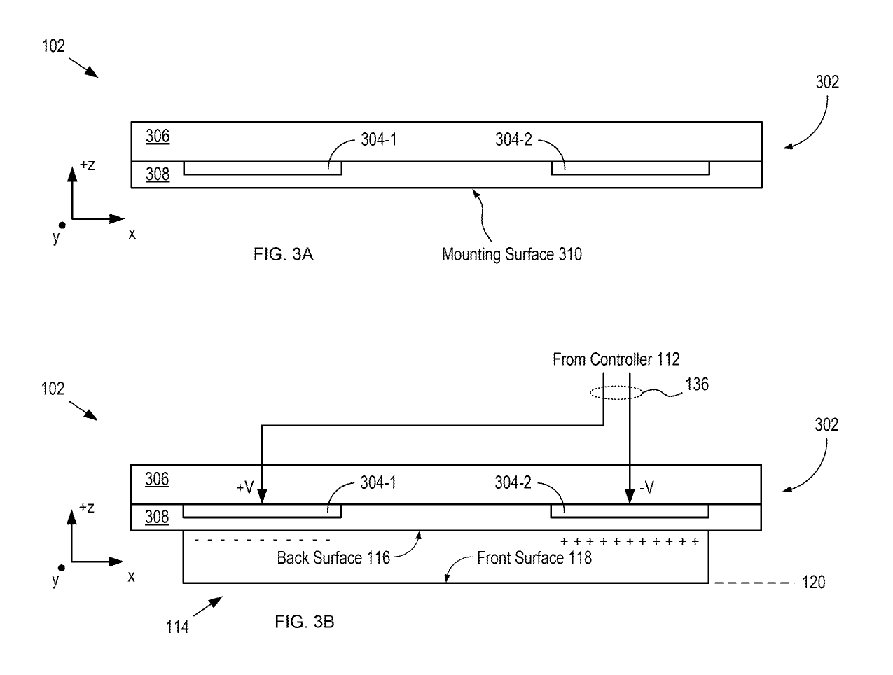

Substrate chuck 102 is a platen for holding substrate 114 via an electrostatic force. Substrate chuck 102 is described in more detail below and with respect to FIGS. 3A-B.

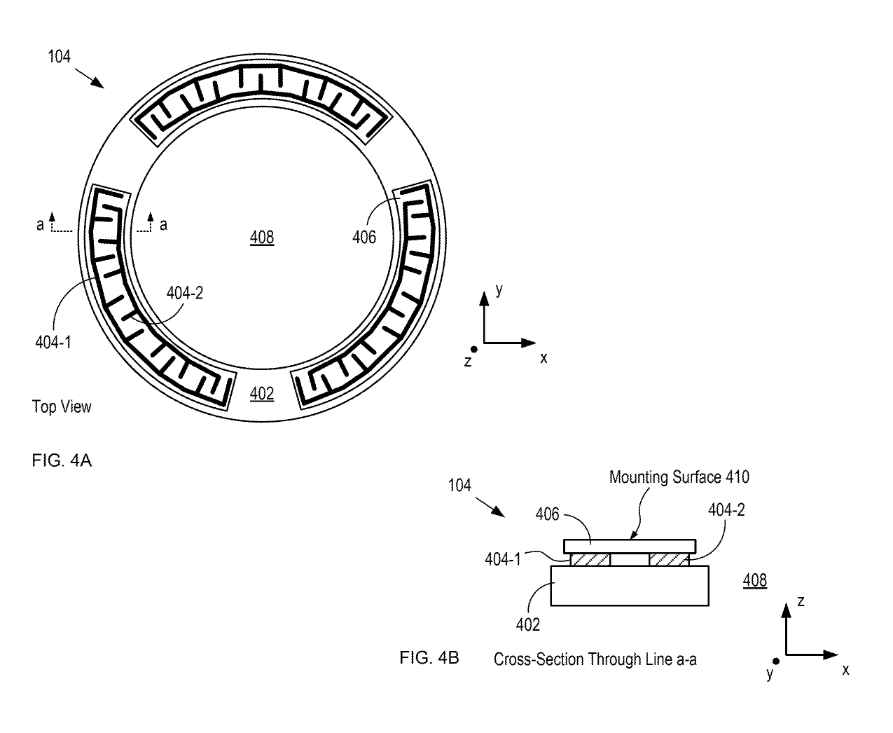

Mask chuck 104 is a fixture for holding the charge-dissipating shadow mask 122 via an electrostatic force imparted on only its back surface. Mask chuck 104 is described in more detail below and with respect to FIGS. 4A-B.

In the depicted example, charge-dissipating shadow mask 122 is a high-precision charge-dissipating shadow mask comprising mask substrate 124 and membrane layer 126, which is suspended over a central opening formed in the mask substrate. Charge-dissipating shadow mask 122 also includes a conductive layer 127 positioned on top of membrane layer 126. Membrane layer 126 and conductive layer 127 each include a through-hole pattern 128.

Charge-dissipating shadow mask 122 includes two major surfaces—front surface 130 and back surface 132. Front surface 130 is the top surface of conductive layer 127 (i.e., the conductive layer surface distal to membrane layer 126), which defines plane 134. Back surface 132 is the surface of mask substrate 124 (i.e., the substrate surface distal to membrane layer 126).

The conductive layer 127 helps dissipate charges that form on the surface of the charge-dissipating shadow mask 122 as a result of the voltages used to generate the electrostatic forces that hold the charge-dissipating shadow mask 122 against the mask chuck 104. This reduces the attractive forces generated between the substrate 114 and the charge-dissipating shadow mask 122 when the substrate 114 and charge-dissipating shadow mask 122 are brought into extremely close proximity in order to reduce feathering affects. As discussed above, these attractive forces can interfere with the alignment of the substrate 114 and charge-dissipating shadow mask 122, and could also result in the substrate 114 and charge-dissipating shadow mask 122 sticking together. Thus, the conductive layer 127 allows for the substrate 114 and charge-dissipating shadow mask 122 to be brought into closer proximity than would otherwise be possible without the conductive layer 127.

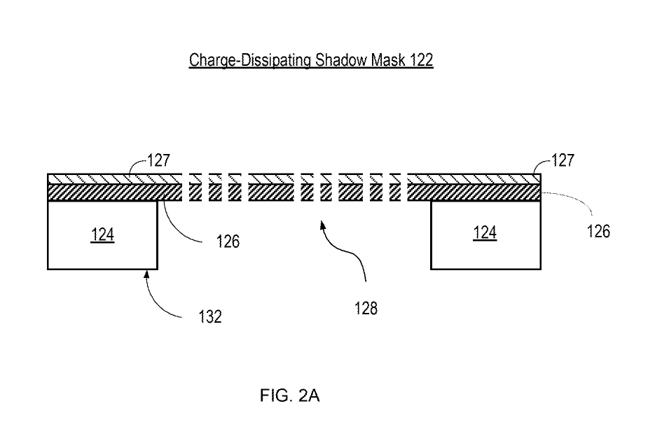

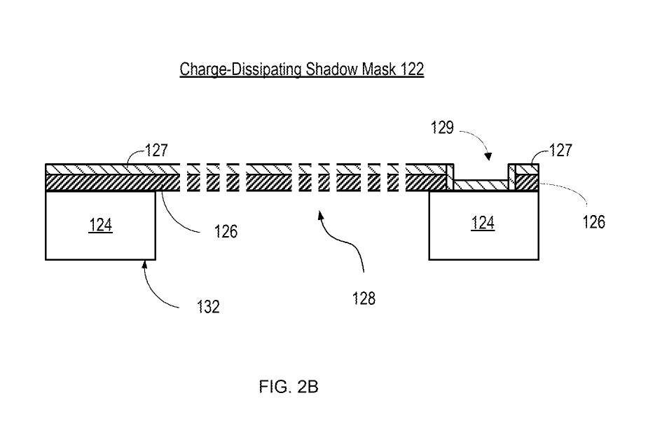

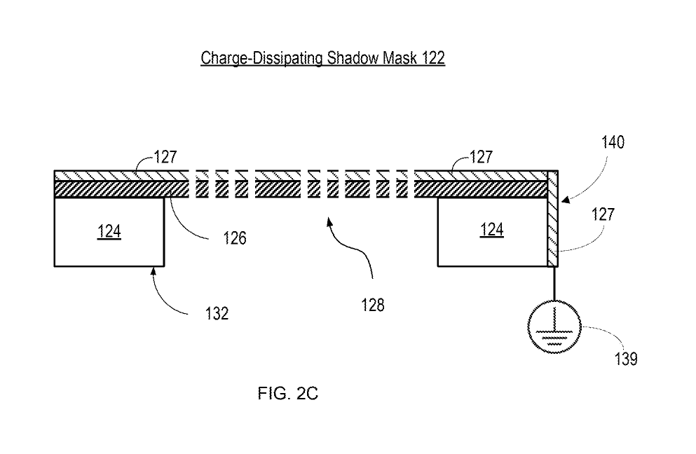

As discussed above, and as will be described in more detail below in connection with FIGS. 2A-2C, the conductive layer 127: (1) can be positioned on top of the membrane layer 126 such that it only contacts the membrane layer 126; (2) can be configured so that a portion of the conductive layer 127 extends through membrane layer 126 so as to contact the mask substrate 124; or (3) may be grounded. Although in the depicted example, the conductive layer 127 is shown fully covering the membrane layer 126, it may also be configured to only partially cover the membrane layer 126.

Source 106 is a crucible for vaporizing material 118, which is an organic material that emits light at a desired wavelength. In the depicted example, source 106 is a single-chamber crucible that is centered with respect to substrate 114; however, in some embodiments, source 106 includes a plurality of chambers that are arranged in one- and/or two-dimensional arrangements. When material 118 is melted or sublimed within the low-pressure atmosphere of chamber 110, vaporized atoms of material 118 are ejected from the source and propagate toward substrate 114 in substantially ballistic fashion.

Alignment system 108 is a high-precision alignment system for controlling the relative position between substrate 114 and charge-dissipating shadow mask 122. In the depicted example, alignment system 108 is capable of independently controlling the position of each of substrate chuck 102 and mask chuck 104 in six dimensions. It is also capable of controlling the position of source 106 so that the source can be moved relative to the substrate/charge-dissipating shadow mask combination to improve deposition uniformity across the substrate, if desired.

Vacuum chamber 110 is a conventional pressure vessel for containing a low-pressure environment required for the evaporation of material 118. In the depicted example, vacuum chamber 110 is a standalone unit; however, it can also be realized as a part of a cluster deposition system or track-deposition system without departing from the scope of the present invention. In some embodiments, vacuum chamber 110 includes several evaporation sources/charge-dissipating shadow mask combinations that enable formation of different patterns of different materials on substrate 114, such as, for example, multiple light-emitting subpixels that emit light at different colors (e.g., red, green, and blue).

Controller 112 is a conventional instrument controller that, among other things, provides control signals 136 and 138 to substrate chuck 102 and mask chuck 104, respectively.

FIG. 2A is a schematic drawing of a cross-sectional view of a charge-dissipating shadow mask 122, in accordance with a first illustrative embodiment of the present invention. In the embodiment depicted in FIG. 2A, the conductive layer 127 is deposited on top of membrane layer 126 such that it is only in contact with membrane layer 126.

FIG. 2B is a schematic drawing of a cross-sectional view of a charge-dissipating shadow mask 122, in accordance with a second illustrative embodiment of the present invention. In the embodiment depicted in FIG. 2B, an opening 129 is created in membrane layer 126 such that a portion of deposited conductive layer 127 contacts substrate 124.

FIG. 2C is a schematic drawing of a cross-sectional view of a charge-dissipating shadow mask 122, in accordance with a third illustrative embodiment of the present invention. In the embodiment depicted in FIG. 2C, the conductive layer 127 extends down a side 140 of the membrane layer 126 and mask substrate 124 and the conductive layer 127 is connected to ground 139. In the embodiment depicted in FIG. 2C, the conductive layer 127 is extended down the side 140 of the membrane layer 126 and mask substrate 124 in order to facilitate connecting the conductive layer 127 to ground 139. However, although not shown, it should be appreciated that in the embodiments depicted in FIGS. 2A-B, the conductive layer 127 could also optionally be connected to ground.

The conductive layer 127 can be comprised of any conductive material, including metals (e.g., gold, chromium, aluminum, etc.), conductive oxides (e.g., tin-doped indium oxide, aluminum doped zinc oxide, etc.), semiconductors, conductive polymers (e.g., Poly(3,4-ethylenedioxythiophene), Poly(4,4-dioctyl cyclopentadithiophene), etc.) or carbons (e.g., carbon nanotubes, graphene, etc.). The conductive layer 127 can be deposited by any standard techniques known in the art, including, but not limited to, evaporation, sputtering, chemical vapor deposition, spin coating and printing. The conductive layer 127 can be deposited before or after the etching of the openings in the membrane layer 126. The thickness of conductive layer 127 is preferably between 10 Angstroms and 5 microns.

FIG. 3A is a schematic drawing of a cross-sectional view of a substrate chuck 102 in accordance with the illustrative embodiment. Substrate chuck 102 includes platen 302 and electrodes 304-1 and 304-2.

Platen 302 is a structurally rigid platform comprising substrate 306 and dielectric layer 308. Each of substrate 306 and dielectric layer 308 includes an electrically insulating material, such as glass, ceramic, anodized aluminum, composite materials, Bakelite, and the like to electrically isolate electrodes 304-1 and 304-2 from each other and from substrate 114 when it is mounted on the substrate chuck 102.

Electrodes 304-1 and 304-2 are electrically conductive elements formed on the surface of substrate 306 and overcoated by dielectric layer 308 to embed them within platen 302. Electrodes 304-1 and 304-2 are electrically coupled with controller 112. It should be noted that electrodes 304-1 and 304-2 are depicted as simple plates; however, in practice, substrate chuck 102 can have electrodes that are shaped in any manner, such as interdigitated comb fingers, concentric rings, irregular shapes, etc. Dielectric layer 308 is a structurally rigid layer of glass disposed over electrodes 304-1 and 304-2 to give rise to mounting surface 310.

FIG. 3B is a schematic drawing of a cross-sectional view of substrate chuck 102 while holding substrate 114. To hold substrate 114 in substrate chuck 102, control signal 136 generates a voltage potential between electrodes 304-1 and 304-2. When back surface 116 is brought into contact with mounting surface 310 (i.e., the top surface of dielectric layer 308), sympathetic charge regions develop within substrate 114 as shown. As a result, an electrostatic force is selectively imparted on back surface 116, thereby attracting it to mounting surface 310.

FIGS. 4A-B are schematic drawings of top and cross-section views, respectively, of a mask chuck 104, in accordance with an illustrative embodiment. The cross-section depicted in FIG. 4B is taken through line a-a shown in FIG. 4A. Mask chuck 104 includes frame 402, electrodes 404-1 and 404-2, and pads 406.

Frame 402 is a structurally rigid circular ring of electrically insulating material. Frame 402 surrounds opening 408, which is sufficiently large to expose the entirety of through-hole pattern 128. In some embodiments, frame 402 has a shape other than circular, such as square, rectangular, irregular, etc. In some embodiments, frame 402 comprises an electrically conductive material that is coated with an electrical insulator.

Electrodes 404-1 and 404-2 are electrically conductive elements formed on the surface of frame 402. Electrodes 404-1 and 404-2 are electrically coupled with controller 112.

Pads 406 are structurally rigid plates of electrically insulating material disposed on electrodes 404-1 and 404-2. Each of pads 406 includes mounting surface 410, against which charge-dissipating shadow mask 122 is held when mounted in the mask chuck 104.

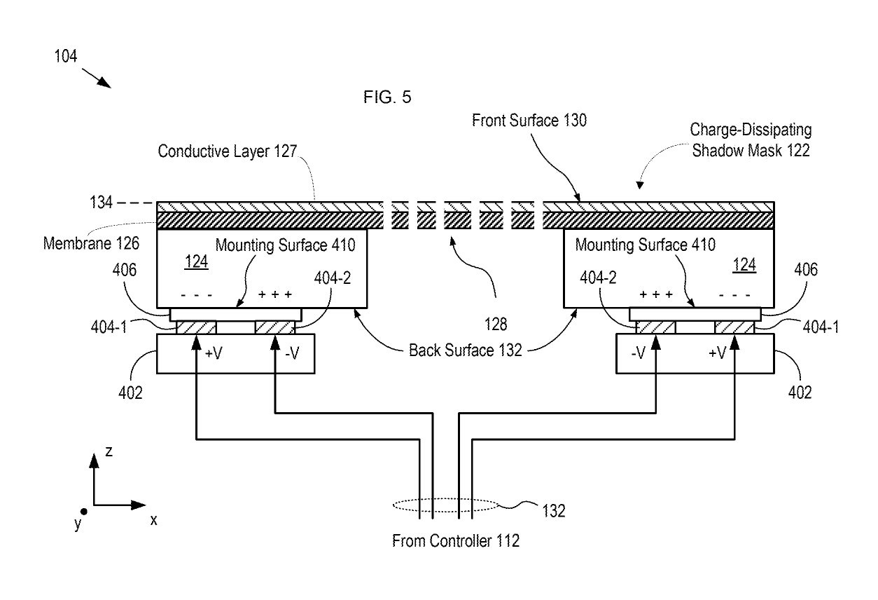

FIG. 5 is a cross-sectional view of charge-dissipating shadow mask 122 mounted in mask chuck 104. Charge-dissipating shadow mask 122 is held in mask chuck 104 by an electrostatic force imparted between mounting surface 410 and back surface 132. The electrostatic force arises in response to a voltage potential between electrodes 404-1 and 404-2, which is generated by control signal 138. When back surface 132 is brought into contact with mounting surface 410, sympathetic charge regions develop within mask substrate 124, as shown. As a result, the electrostatic force is selectively imparted between back surface 132 and mounting surface 410.

In operation, alignment system 108 aligns substrate 114 and charge-dissipating shadow mask 122 by controlling the position of substrate chuck 102. In some embodiments, alignment system 108 aligns the substrate 114 and charge-dissipating shadow mask 122 by controlling the position of mask chuck 104. In some embodiments, the positions of both chucks is controlled to align the substrate 114 and charge-dissipating shadow mask 122.

In a preferred embodiment, neither substrate chuck 102 nor mask chuck 104 includes any structural element that projects past its respective mounting surface. As a result of this and the charge dissipating properties of the charge-dissipating shadow mask 122, the substrate 114 and charge-dissipating shadow mask 122 can be aligned with little or no separation between them to mitigate feathering during deposition. One skilled in the art will recognize that in conventional direct-deposition systems, the separation between substrate and shadow mask must be at least a few tens, or even hundreds, of microns due to structural elements that project past the mounting surfaces of the chucks used to hold the shadow mask and substrate and/or due to the attractive forces generated between the substrate and the shadow mask when electrostatic chucks are used.

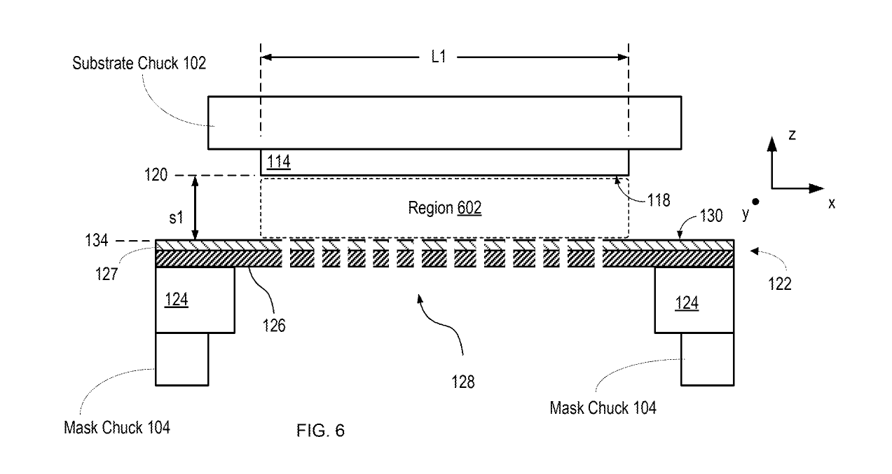

FIG. 6 is a schematic drawing of a cross-sectional view of a portion of system 100 with substrate 114 and charge-dissipating shadow mask 122 in alignment for deposition of material 118.

When the substrate 114 and charge-dissipating shadow mask 122 are aligned, they collectively define region 602 between them. Region 602 has a lateral extent, L1, which is equal to that of front surface 118. Region 602 also has a thickness that is equal to the separation, s1, between planes 120 and 134 (i.e., the separation between the substrate 114 and the charge-dissipating shadow mask 122).

Because no portion of substrate chuck 102 extends past plane 120 into region 602, there is no obstruction between the substrate 114 and the charge-dissipating shadow mask 122. In addition, charge-dissipating shadow mask 122 incorporates a conductive layer 127, that helps dissipate charges that form on the surface of the charge-dissipating shadow mask 122 as a result of the voltages used to generate the electrostatic forces that hold the charge-dissipating shadow mask 122 against the mask chuck 104. As discussed above, this reduces the attractive forces generated between the substrate 114 and the charge-dissipating shadow mask 122 when the substrate 114 and charge-dissipating shadow mask 122 are brought into extremely close proximity.

As a result, separation, s1, between substrate 114 and charge-dissipating shadow mask 122 can be extremely small (10 microns). Indeed, it can be smaller than would otherwise be possible if one used a prior art shadow mask with no charge-dissipating capabilities. The ability to perform direct patterning with a substrate/shadow mask separation equal to or less than 10 microns affords embodiments of the present invention particular advantage over prior-art direct-patterning deposition systems because it enables feathering to be significantly reduced or even eliminated.

In operation, source 106 (shown in FIG. 1) is heated to vaporize material 118 to realize a patterned layer of the material on front surface 118 of substrate 114.

In some embodiments, mask chucks in accordance with the present invention include one or more features that mitigate or eliminate gravity-induced sag of a shadow mask when the charge-dissipating shadow mask 122 is mounted. As discussed in detail in U.S. patent application Ser. No. 15/597,635 filed on May 17, 2017 (Attorney Docket: 6494-208US1), which is incorporated herein by reference, a shadow mask can sag by several microns in the center due to its own mass and the effect of gravity. This gravity-induced sag leads to several significant issues that exacerbate feathering. First, it increases the separation between the shadow mask and the substrate in the center of the deposition region, which is typically centered on the shadow mask. As discussed above, feathering increases with substrate/shadow mask separation distance. Second, it leads to a non-uniform separation between the substrate and the shadow mask, which gives rise to a variation in the degree of feathering that occurs across the substrate surface. The non-uniformity makes it difficult, if not impossible, to compensate for feathering via creative mask layout. It is yet another aspect of the present invention that a mask chuck can include features that mitigate gravity-induced sag of a shadow mask.

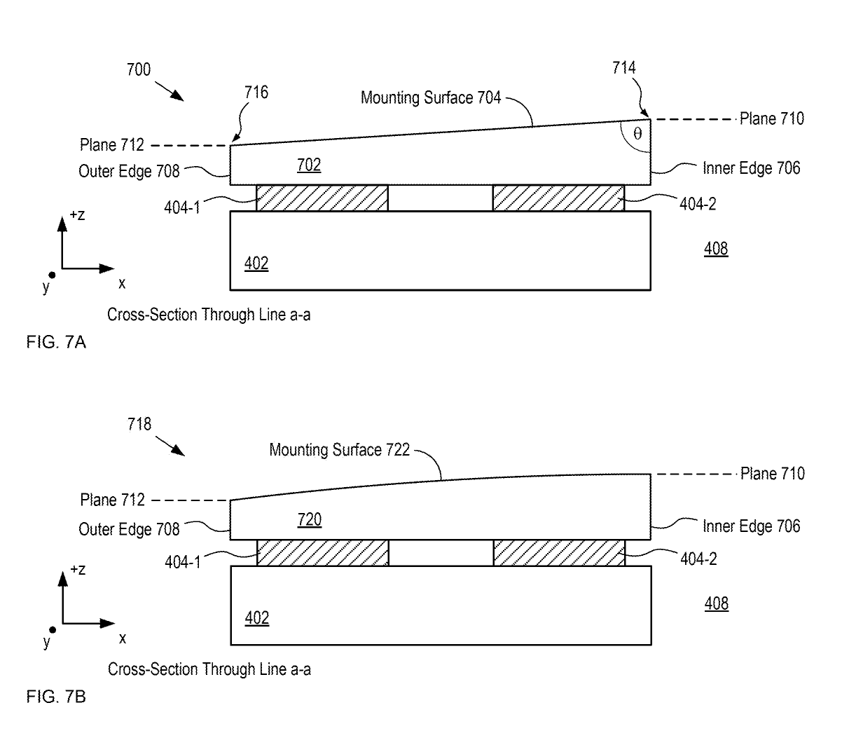

FIG. 7A is a schematic drawing of a cross-sectional view of a portion of a mask chuck, in accordance with a first alternative embodiment of the present invention. The cross-section depicted in FIG. 7A is taken through line a-a shown in FIG. 4A. Mask chuck 700 includes frame 402, electrodes 404-1 and 404-2, and pads 702.

Pads 702 are analogous to pads 406 described above; however, each pad 702 has a mounting surface that is designed to induce or increase tensile strain in the shadow-mask when it is mounted in the mask chuck. Pad 702 has mounting surface 704, which is linearly tapered downward from inner edge 706 (i.e., the edge proximal to opening 408) to outer edge 708. In other words, mounting surface 704 tapers in the negative z-direction, as shown, from point 714 to point 716 (i.e., where from it meets inner edge 706 at plane 710 to where it meets outer edge 708 at plane 712). In embodiments in which inner edge 706 is perpendicular to plane 710, therefore, inner edge 706 and mounting surface 704 form interior angle, θ, such that it is an acute angle.

When charge-dissipating shadow mask 122 is held in mask chuck 700, back surface 132 is attracted to mounting surface 704, thereby inducing a curvature in the shadow mask that increase the laterally directed tension in front surface 130 of the charge-dissipating shadow mask 122. As a result, the membrane is pulled tighter and gravity-induced sag is reduces or eliminated.

FIG. 7B is a schematic drawing of a cross-sectional view of a portion of a mask chuck, in accordance with a second alternative embodiment of the present invention. The cross-section depicted in FIG. 7B is taken through line a-a shown in FIG. 4A. Mask chuck 718 includes frame 402, electrodes 404-1 and 404-2, and pads 720.

Pads 720 are analogous to pads 406 described above; however, like pads 702, each pad 720 has a mounting surface that is designed to induce or increase tensile strain in the shadow-mask when it is mounted in the mask chuck. Pad 720 has mounting surface 722, which curves downward (i.e., in the negative z-direction, as shown) from inner edge 706 to outer edge 708. In other words, mounting surface 722 tapers in the negative z-direction, as shown, from point 714 to point 716.

When charge-dissipating shadow mask 122 is held in mask chuck 718, back surface 132 is attracted to mounting surface 722, thereby inducing a curvature in the shadow mask that increase the laterally directed tension in front surface 130 of the charge-dissipating shadow mask 122. As a result, the membrane is pulled tighter and gravity-induced sag is reduced or eliminated. In some embodiments, the amount of additional tension induced in front surface 130 can be controlled by controlling the magnitude of the voltage differential applied to electrodes 404-1 and 404-2.

It will be clear to one skilled in the art, after reading this Specification, that the directions in which mounting surfaces 704 and 722 slope (or curve) would be reversed for a deposition system in which the charge-dissipating shadow mask 122 were mounted upside down as compared to its orientation depicted in FIG. 1. Further, in such a configuration, it would typically be necessary that substrate chuck 102 be designed to enable substrate 114 to reside within opening 408 to enable a substrate/shadow mask separation of less than or equal to 10 microns.

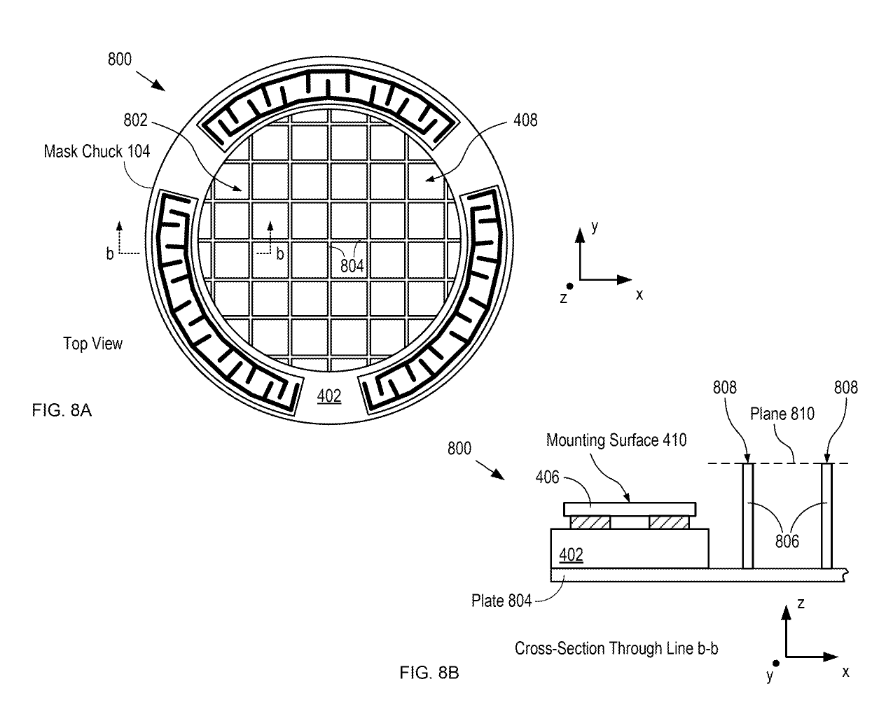

FIGS. 8A-B are schematic drawings of top and cross-section views, respectively, of a mask chuck in accordance with a third alternative embodiment of the present invention. Mask chuck 800 includes mask chuck 104 and support grid 802. Support grid 802 includes plate 804 and support ribs 806.

Plate 804 is a rigid plate from which support ribs 806 extend. In some embodiments, plate 804 and support ribs 806 are machined from a solid body of structural material. Materials suitable for use in plate 804 and support ribs 806 include, without limitation, metals, plastics, ceramics, composite materials, glasses, and the like. Plate 804 is designed to mount to frame 402 to locate support grid 802 within opening 408 such that it mechanically supports membrane layer 126 when charge-dissipating shadow mask 122 is mounted in mask chuck 800.

Support ribs 806 are arranged to support charge-dissipating shadow mask 122 in regions that lie between the through-holes of through-hole arrangement 128. Typically, the through-holes of the charge-dissipating shadow mask 122 are arranged in clusters that correspond to different die regions on the substrate 114. Since these die regions are usually separated by “lanes” intended for removal by a dicing saw, support ribs 806 are preferably arranged to match the arrangement of these lanes. It should be noted, however, that any suitable arrangement of support ribs can be used in support grid 802.

Support grid 802 is formed such that their top surfaces 808 are coplanar and define plane 810. Plane 810 lies above mounting surface 410 by a distance equal to the thickness of frame 124. As a result, when frame 124 is in contact with mounting surface 410, support ribs 806 are in contact with membrane layer 126.

In some embodiments, charge-dissipating shadow mask 122 is held upside down in mask chuck 800 such that membrane layer 126 is in contact with mounting surface 410. In such embodiments, support grid 802 is designed to fit within opening 408 such that plane 810 is coplanar with mounting surface 410. As a result, membrane layer 126 is supported by support grid 802 such that it is perfectly level all the way across opening 408.

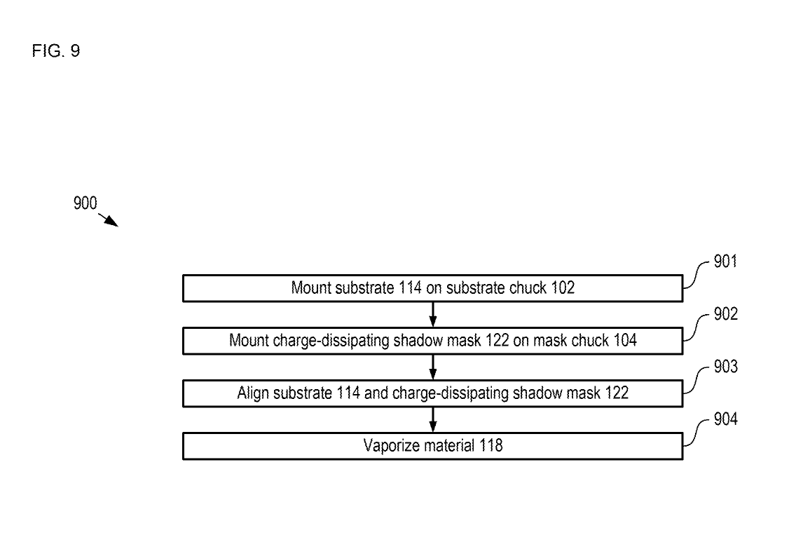

FIG. 9 is a flowchart of methods of an operation for forming a patterned layer of material on a substrate, in accordance with an illustrative embodiment of the present invention. The method 900 begins with operation 901, where a substrate 114 is mounted on substrate chuck 102, as illustrated and described above in connection with FIGS. 3A and 3B. Then, at operation 902, the charge-dissipating shadow mask 122 is mounted on mask chuck 104, as illustrated and described above in connection with FIGS. 4A and 4B.

At operation 903, alignment system 108 aligns substrate 114 and shadow mask 122 by controlling the position of substrate chuck 102, as illustrated and described above in connection with FIGS. 5 and 6. At operation 904, source 106 is heated to vaporize material 118 to realize a patterned layer of the material on front surface 118 of substrate 114, as described and illustrated above in connection with FIG. 6.

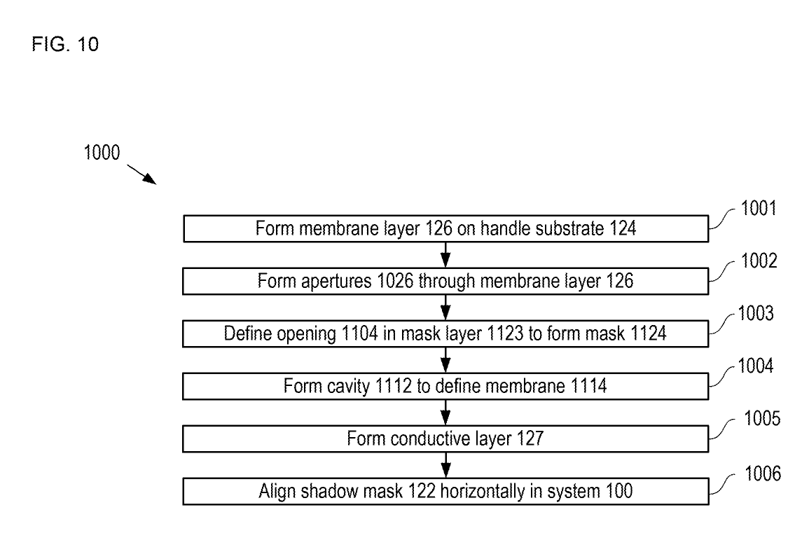

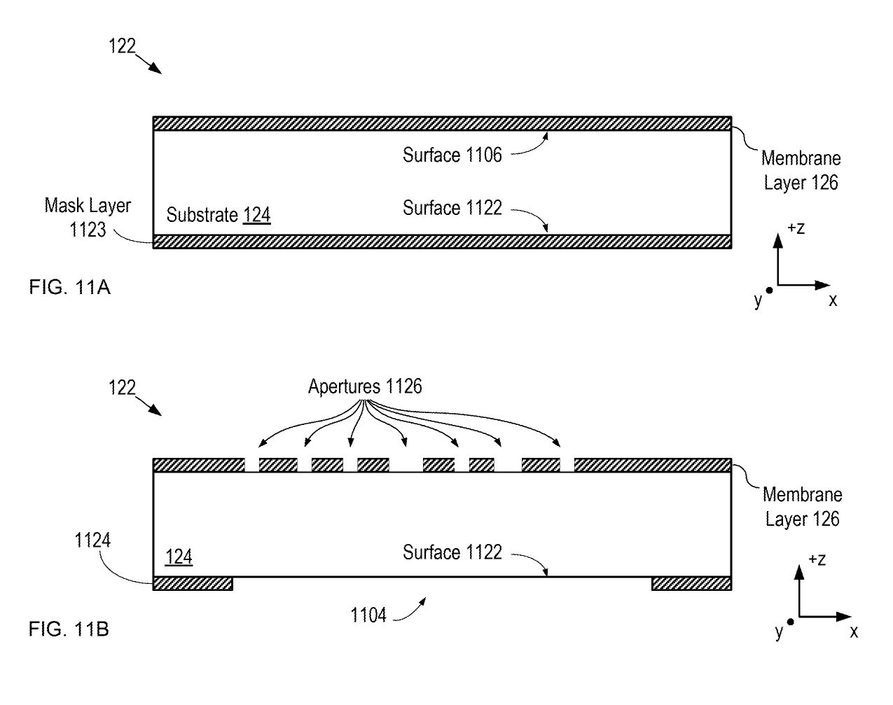

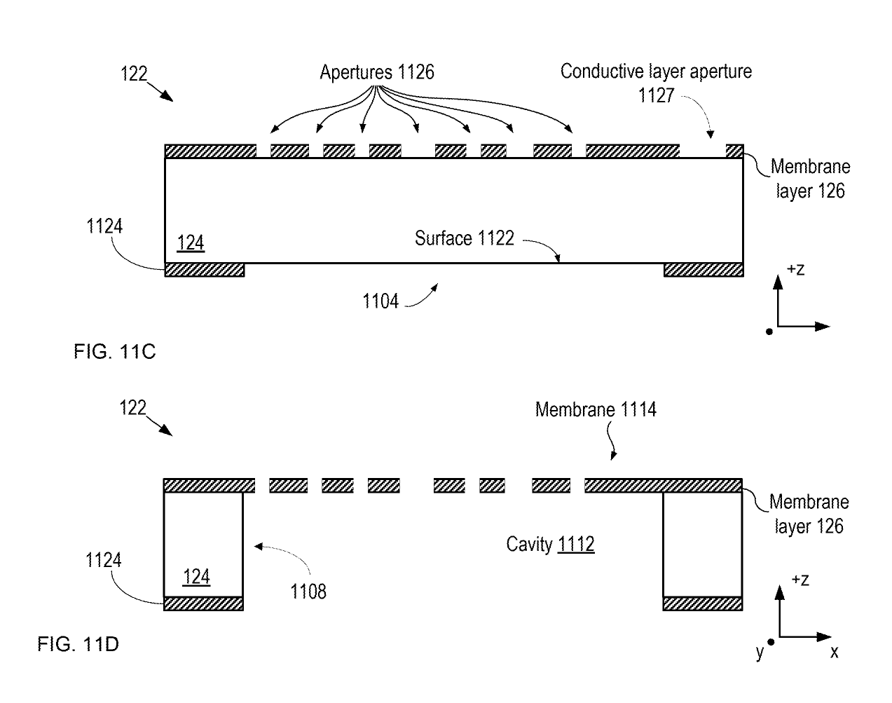

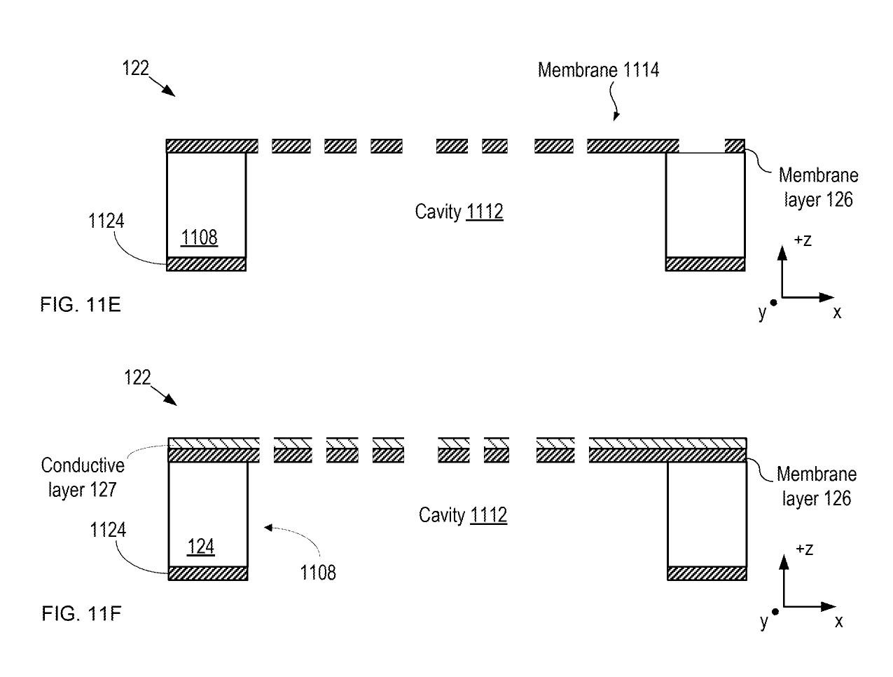

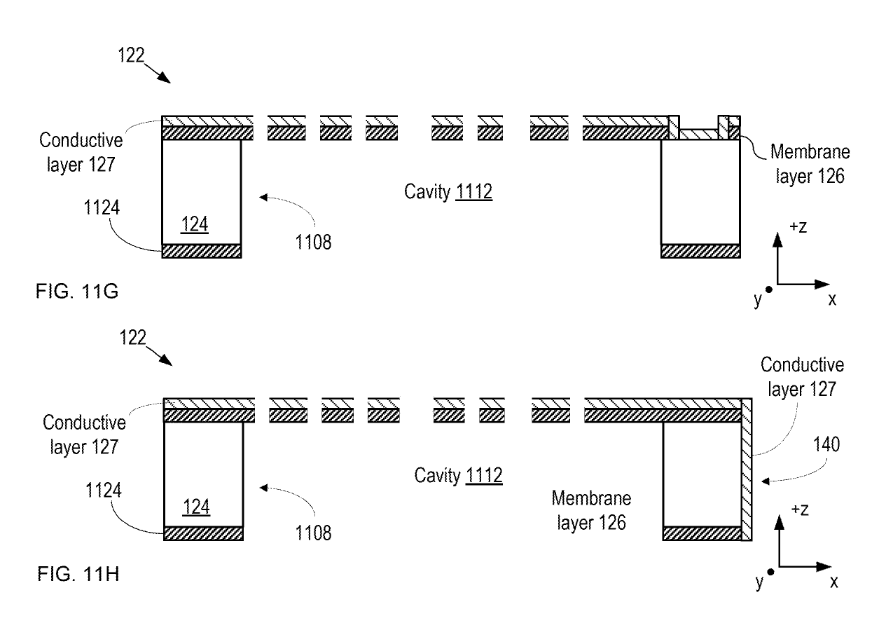

FIG. 10 depicts operations of a method for forming the charge-dissipating shadow mask 122 embodiment illustrated in FIG. 2A. Method 1000 is described herein with continuing reference to FIG. 2, as well as reference to FIGS. 11A-G. Method 1000 begins with operation 1001, wherein membrane layer 126 is formed on mask substrate 124.

Mask substrate 124 is a conventional silicon wafer suitable for use in planar processing. In some embodiments, mask substrate 124 comprises a different material suitable for use in planar processing. Materials suitable for use in mask substrate 124 include, without limitation, silicon compounds, compound semiconductors, other semiconductors, ceramics, composite materials, and the like.

Membrane layer 126 is suitably a layer of stoichiometric silicon nitride having a thickness of preferably approximately 50 nm. Membrane layer 126 is preferably deposited on top surface 1106 of mask substrate 124 via low-pressure chemical vapor deposition (LPCVD). In some embodiments, membrane layer 126 is deposited via a conventional deposition process other than LPCVD, such as atomic-layer epitaxy, plasma-enhanced chemical vapor deposition (PECVD), sputtering, and the like. In some embodiments, membrane layer 126 comprises a material other than stoichiometric silicon nitride, such as silicon-rich silicon nitride, silicon oxynitride, one or more metals, one or more polymers, etc.

Although the membrane layer 126 has been illustrated as a single layer, in some embodiments membrane layer 126 is a composite layer comprised of two or more distinct layers for purposes of mitigating sagging of the membrane layer 126, as discussed and described in detail in U.S. patent application Ser. No. 15/597,635 filed on May 1, 2018 (Attorney Docket: 6494-215US1), which is incorporated herein by reference. For example, the membrane layer 126 can be a composite layer comprised of a silicon nitride layer and a silicon dioxide layer on top of the silicon nitride layer.

In the depicted example, the LPCVD deposition of membrane layer 126 results in deposition of the material on back surface 1122 of mask substrate 124. The layer formed on back surface 1122 collectively define mask layer 1123. In some embodiments, mask layer 1123 includes one or more different materials that are suitable for protecting a portion of surface 1122 during the formation of cavity 1112. In some embodiments, mask layer 1123 is formed independently of membrane layer 126 in a separate operation or set of operations.

FIG. 11A depicts a schematic drawing of a cross-sectional view of nascent charge-dissipating shadow mask 122 after the formation of membrane layer 126 on surface 1106 and mask layer 1123 on surface 1122.

At operation 1002, apertures 1126 are formed through the entire thickness of membrane layer 126.

Apertures 1126 are through-holes formed in membrane layer 126 via reactive-ion etching (RIE). In some embodiments, apertures 1126 are formed in another conventional manner Apertures 1126 are sized and arranged based on the desired pattern of material to be deposited on a target substrate 114. In some embodiments, apertures 1126 are arranged to match the desired pattern of deposited material. In some embodiments, apertures 1126 are arranged in a pattern that compensates for feathering across the area of the mask substrate 124. Typically, apertures 1126 are formed through membrane layer 126 before the formation of cavity 1112.

At operation 1003, mask 1124 is formed on the backside of mask substrate 124.

To form mask 1124, layer 1123 is patterned, typical via photolithography and reactive-ion etching (or another conventional etching process) to define opening 1104, thereby exposing the central region of surface 1122.

FIG. 11B depicts a schematic drawing of a cross-sectional view of nascent charge-dissipating shadow mask 122 after the definition of apertures 1126 and mask 1124. For the charge dissipating shadow mask embodiment of FIG. 2B, a conductive layer aperture 1127 must also be defined such that the conductive layer 127 eventually contacts mask substrate 124. FIG. 11C depicts a schematic drawing of a cross-sectional view of nascent charge-dissipating shadow mask 122 after the definition of apertures 1126 and mask 1124, as well as conductive layer aperture 1127.

At operation 1004, membrane 1114 is defined by releasing a portion of membrane layer 126 from mask substrate 124 by forming cavity 1112. Cavity 1112 is formed by removing the material in the center of mask substrate 124 while leaving the outer portion of mask substrate 124 as an annular support frame 1108, which extends around the perimeter of membrane layer 126. In the depicted example, cavity 112 is formed by removing the exposed silicon region via a crystallographic dependent etch (e.g., ethylene diamine pyrocatechol (EDP), potassium hydroxide (KOH), hydrazine, etc.). In some embodiments, cavity 1112 is formed via deep reactive-ion etching, or other conventional process. In some embodiments, cavity 1112 is formed such that a thin layer of silicon remains in contact with membrane 1114, thereby defining a membrane that includes an additional layer of silicon.

FIG. 11D depicts a schematic drawing of a cross-sectional view of nascent charge-dissipating shadow mask 122 after the formation of cavity 1112, for the charge-dissipating shadow mask embodiment in which the conductive layer 127 does not contact substrate 114. FIG. 11E depicts a schematic drawing of a cross-sectional view of nascent charge-dissipating shadow mask 122 after the formation of cavity 1112, for the charge-dissipating shadow mask embodiment of FIG. 2B in which the conductive layer 127 contacts substrate 114. The mask 1124 may be optionally removed.

At operation 1005, conductive layer 127 is formed on membrane layer 126. FIG. 11F depicts a schematic drawing of a cross-sectional view of nascent charge-dissipating shadow mask 122 after the deposition of conductive layer 127 on membrane layer 126. FIG. 11G depicts a schematic drawing of a cross-sectional view of nascent charge-dissipating shadow mask 122 after the formation of cavity 1112, for the charge-dissipating shadow mask embodiment of FIG. 2B in which the conductive layer 127 contacts substrate 114. FIG. 11H depicts a schematic drawing of a cross-sectional view of nascent charge-dissipating shadow mask 122 after the formation of cavity 1112, for the charge-dissipating shadow mask embodiment of FIG. 2C in which the conductive layer 127 extends down a side 140 of the membrane layer 126 and mask substrate 124.

As discussed above, conductive layer 127 can be comprised of any conductive material, including metals (e.g., gold, chromium, aluminum, etc.), conductive oxides (e.g., tin-doped indium oxide, aluminum doped zinc oxide, etc.), semiconductors, conductive polymers (e.g., Poly(3,4-ethylenedioxy thiophene), Poly(4,4-dioctylcyclopentadithiophene), etc.) or carbons (e.g., carbon nano tubes, graphene, etc.). The conductive layer 127 can be deposited by any standard techniques known in the art, including, but not limited to, evaporation, sputtering, chemical vapor deposition, spin coating and printing. The thickness of conductive layer 127 is preferably between 10 Angstroms and 5 microns.

Although the illustrated embodiments show the conductive layer 127 being deposited after the apertures 1126 and cavity 1112 are formed, in some embodiments the conductive layer 127 can be deposited before apertures 1126 are formed and before the cavity 1112 is formed. Further, the conductive layer 127 can be deposited after apertures 1126 are formed but before the cavity 1112 is formed.

The foregoing embodiments and advantages are merely exemplary, and are not to be construed as limiting the present invention. The description of the present invention is intended to be illustrative, and not to limit the scope of the claims. Many alternatives, modifications, and variations will be apparent to those skilled in the art. Various changes may be made without departing from the spirit and scope of the invention.

What is claimed is:

1. A charge-dissipating shadow mask, comprising:
a membrane layer having a first region that comprises an aperture pattern comprising at least one aperture; and
a conductive layer disposed on the membrane layer.

2. The charge-dissipating shadow mask of claim 1, wherein the conductive layer covers all of the membrane layer.

3. The charge-dissipating shadow mask of claim 1, wherein the conductive layer covers a portion of the membrane layer.

4. The charge-dissipating shadow mask of claim 1, wherein the membrane layer comprises at least one of stoichiometric silicon nitride, silicon-rich silicon nitride, silicon oxynitride, a metal, and a polymer.

5. The charge-dissipating shadow mask of claim 1, wherein the membrane layer comprises a composite layer.

6. The charge-dissipating shadow mask of claim 5, wherein the composite layer comprises a silicon nitride layer and a silicon dioxide layer disposed on the silicon nitride layer.

7. The charge-dissipating shadow mask of claim 1, wherein the conductive layer comprises at least one of a metal, a conductive oxide, a semiconductor, a conductive polymer, and a carbon.

8. The charge-dissipating shadow mask of claim 1, wherein the membrane layer is disposed on a mask substrate, wherein the mask substrate comprises a cavity over which a portion of the membrane is disposed.

9. The charge-dissipating shadow mask of claim 8, wherein the mask substrate comprises a silicon wafer.

10. The charge-dissipating shadow mask of claim 8, wherein the conductive layer is in physical contact with the mask substrate via an opening in the membrane layer.

11. The charge-dissipating shadow mask of claim 1, wherein the conductive layer is grounded.

12. A system for depositing a pattern of material on a substrate, comprising:
a first electrostatic chuck for holding the substrate via an electrostatic force;
a charge dissipating shadow mask, wherein the charge dissipating shadow mask comprises:
a membrane layer having a first region that comprises an aperture pattern comprising at least one aperture, and
a conductive layer disposed on the membrane layer;
a second electrostatic chuck for holding the charge dissipating shadow mask via an electrostatic force; and
an alignment system for controlling the relative position of the first chuck and the second chuck to align the shadow mask and the substrate.

13. The charge-dissipating shadow mask of claim 12, wherein the conductive layer covers all of the membrane layer.

14. The charge-dissipating shadow mask of claim 12, wherein the conductive layer covers a portion of the membrane layer.

15. The charge-dissipating shadow mask of claim 12, wherein the membrane layer comprises at least one of stoichiometric silicon nitride, silicon-rich silicon nitride, silicon oxynitride, a metal, and a polymer.

16. The charge-dissipating shadow mask of claim 12, wherein the membrane layer comprises a composite layer.

17. The charge-dissipating shadow mask of claim 16, wherein the composite layer comprises a silicon nitride layer and a silicon dioxide layer disposed on the silicon nitride layer.

18. The charge-dissipating shadow mask of claim 12, wherein the conductive layer comprises at least one of a metal, a conductive oxide, a semiconductor, a conductive polymer, and a carbon.

19. The charge-dissipating shadow mask of claim 12, wherein the membrane layer is disposed on a mask substrate, wherein the mask substrate comprises a cavity over which a portion of the membrane is disposed.

20. The charge-dissipating shadow mask of claim 19, wherein the mask substrate comprises a silicon wafer.

21. The charge-dissipating shadow mask of claim 19, wherein the conductive layer is in physical contact with the mask substrate via an opening in the membrane layer.

22. The charge-dissipating shadow mask of claim 12, wherein the conductive layer is grounded.

23. A method of forming a shadow mask, comprising:
providing a mask substrate;
forming a membrane layer on the mask substrate;
forming an aperture pattern in a first region of the membrane layer, wherein the aperture pattern comprises at least one aperture that extends completely through the membrane layer;
forming a conductive layer on the membrane layer; and
forming a cavity in the mask substrate, wherein the formation of the cavity releases the first region of the membrane layer to define a membrane.

24. The method of claim 23, wherein the conductive layer is formed on the membrane layer after the aperture pattern and cavity are formed.

25. The method of claim 23, wherein the conductive layer is formed after the aperture pattern is formed and before the cavity is formed.

26. The method of claim 23, wherein the conductive layer is formed before the aperture pattern is formed and before the cavity is formed, and wherein the step of forming an aperture pattern comprises forming an aperture pattern in a first region of the membrane layer and a corresponding first region of the conductive layer.

27. The method of claim 23, wherein the conductive layer is formed so as to cover all of the membrane layer.

28. The method of claim 23, wherein the conductive layer is formed so as to cover a portion of the membrane layer.

29. The method of claim 23, wherein the membrane layer comprises at least one of stoichiometric silicon nitride, silicon-rich silicon nitride, silicon oxynitride, a metal, and a polymer.

30. The method of claim 1, wherein the membrane layer comprises a composite layer.

31. The method of claim 30, wherein the composite layer comprises a silicon nitride layer and a silicon dioxide layer disposed on the silicon nitride layer.

32. The method of claim 23, wherein the conductive layer comprises at least one of a metal, a conductive oxide, a semiconductor, a conductive polymer, and a carbon.

33. The method of claim 23, wherein the mask substrate comprises a silicon wafer.

34. The method of claim 23, further comprising:
forming an opening in the membrane layer that extends to the mask substrate; and
forming the conductive layer on the membrane layer after the opening in the membrane layer is formed, so that the conductive layer contacts the mask substrate via the opening in the membrane layer.

35. The method of claim 23, further comprising connecting the conductive layer to ground potential.
